(19) United States
(12) Patent Application Publication
(10) Pub. No.: US 2026/0363015 A1
(43) Pub. Date: Nov. 12, 2026

(54) APPARATUS AND METHOD FOR MANUFACTURING DISPLAY APPARATUS, AND APPARATUS FOR MANUFACTURING ELECTRONIC DEVICE

(71) Applicant: Samsung Display Co., Ltd., Yongin-si (KR)

(72) Inventor: Jongik LEE, Yongin-si (KR)

(73) Assignee: Samsung Display Co., Ltd., Yongin-si (KR)

(21) Appl. No.: 19/559,545

(22) Filed: Mar. 6, 2026

(30) Foreign Application Priority Data
May 7, 2025 (KR) 10-2025-0059252

(51) Int. Cl. H10P 72/00; B32B 37/00; B32B 37/10; H10H 29/01; H10K 59/80

(52) U.S. Cl. CPC H10P 72/0438; B32B 37/0046; B32B 37/10; H10H 29/012; H10K 59/87; B32B 2457/206; B32B 2457/208

(57) ABSTRACT

Provided is an apparatus for manufacturing a display apparatus, the apparatus including a chamber, a first stage unit inside the chamber, a second stage unit facing the first stage unit, a panel receiving unit between the first stage unit and the second stage unit, and the panel receiving unit configured to support a bonding panel, and a cylinder configured to move up to press the first stage unit toward the second stage unit. As the cylinder moves up, the first stage unit moves up to contact the panel receiving unit, and the first stage unit and the panel receiving unit are configured to move up together to press the bonding panel between the first stage unit and the second stage unit.

### CROSS-REFERENCE TO RELATED APPLICATION

This application is based on and claims priority under 35 U.S.C. § 119 to Korean Patent Application No. 10-2025-0059252, filed on May 7, 2025, in the Korean Intellectual Property Office, the disclosure of which is incorporated by reference herein in its entirety.

### BACKGROUND

Example embodiments relate to an apparatus for manufacturing a display apparatus, a method for manufacturing a display apparatus, and an apparatus for manufacturing an electronic device, and more particularly, to an apparatus for manufacturing a display apparatus, a method for manufacturing a display apparatus, and an apparatus for manufacturing an electronic device all of which are capable of improving the quality of a display apparatus.

Electronic devices have been widely used recently in various ways such as portable electronic devices and stationary electronic devices. Such electronic devices may include a display apparatus that may provide visual information such as images and/or videos to users to support various functions.

The display apparatus may be formed by bonding a display substrate including a pixel circuit and a touch screen panel including a touch sensor. In this case, a filler may be injected between the display substrate and the touch screen panel and may provide cushioning therebetween. The filler may be cured after injection to form a protective layer. The filler may be quickly and evenly spread on a panel surface which may reduce or prevent defects from occurring in the display apparatus. Thus, there may be a reduction in the manufacturing time of the display device and/or a quality of the display device may be improved.

The above-described background art is technical information for deriving the disclosure or acquired during the process of deriving the disclosure, and may not necessarily be known art disclosed to the general public before filing the disclosure.

### SUMMARY

Example embodiments include an apparatus for manufacturing a display apparatus, a method for manufacturing a display apparatus, and an apparatus for manufacturing an electronic device all of which are capable of improving the quality of a display apparatus.

However, these objectives are provided as example embodiments, and the objectives to be solved by the disclosure are not necessarily limited thereto.

Additional aspects will be set forth in part in the description which follows and, in part, will be apparent from the description, or may be learned by practice of the presented example embodiments of the disclosure.

According to one or more example embodiments, an apparatus for manufacturing a display apparatus includes a chamber, a first stage unit inside the chamber, a second stage unit facing the first stage unit, a panel receiving unit between the first stage unit and the second stage unit, and the panel receiving unit configured to support a bonding panel, and a cylinder configured to move up to press the first stage unit toward the second stage unit. As the cylinder moves up, the first stage unit moves up to contact the panel receiving unit, and the first stage unit and the panel receiving unit are configured to move up together to press the bonding panel between the first stage unit and the second stage unit.

According to one or more example embodiments, a method of manufacturing a display apparatus includes seating a bonding panel, the bonding panel comprising a first panel, a second panel, a filler injected between the first panel and the second panel, and a dam unit along a circumference of the first panel in a panel receiving unit, raising a cylinder to raise a first stage unit, further raising the cylinder to raise the first stage unit and the panel receiving unit together, and further raising the cylinder toward a second stage unit and pressing the bonding panel seated in the panel receiving unit with the first stage unit and the second stage unit.

According to one or more example embodiments, an apparatus for manufacturing an electronic device includes a chamber, a first stage unit inside the chamber, a second stage unit facing the first stage unit, a panel receiving unit between the first stage unit and the second stage unit, and the panel receiving unit configured to support a bonding panel, and a cylinder configured to move up to press the first stage unit toward the second stage unit. The first stage unit is configured to move up as the cylinder moves up to contact the panel receiving unit, and the first stage unit and the panel receiving unit are configured to move up together as the cylinder moves up to press the bonding panel between the first stage unit and the second stage unit.

Other aspects, features, and advantages other than those described above will become apparent from the following detailed description, claims, and drawings for carrying out the disclosure.

### BRIEF DESCRIPTION OF THE DRAWINGS

The above and other aspects, features, and advantages of some example embodiments of the present disclosure will be more apparent from the following description taken in conjunction with the accompanying drawings, in which:

FIG. 1 is a schematic plan view of an apparatus for manufacturing a display apparatus according to some example embodiments;

FIG. 2 is a schematic perspective view of a press unit according to some example embodiments;

FIG. 3 is a schematic front view of a press unit according to some example embodiments and may be a view taken in direction III of FIG. 2;

FIG. 4 is a schematic side view of a press unit according to some example embodiments and may be a view taken in direction IV of FIG. 2;

FIG. 5 is a schematic perspective view of a fixed stage unit according to some example embodiments;

FIG. 6 is a schematic front view of a transfer unit according to some example embodiments;

FIG. 7 is a schematic bottom view of a transfer unit according to some example embodiments;

FIG. 8 is a schematic perspective view of a first stage unit according to some example embodiments;

FIG. 9 is a schematic side view of a first stage unit according to some example embodiments;

FIGS. 10 and 11 are schematic side views of a stopper unit disposed on a first base plate;

FIG. 12 is a schematic cross-sectional view of a first stage according to some example embodiments;

FIG. 13 is a schematic perspective view of a panel receiving unit according to some example embodiments;

FIG. 14 is a schematic perspective view of a panel adjustment unit according to some example embodiments and is an enlarged view of portion XIV of FIG. 13;

FIGS. 15 and 16 are schematic front views of a panel adjustment unit according to some example embodiments and show an operation of the panel adjustment unit;

FIG. 17 is a schematic front view of a second stage unit according to some example embodiments;

FIGS. 18 to 23 are schematic views showing a method of manufacturing a display apparatus according to some example embodiments;

FIG. 24 is a block diagram of an electronic device according to some example embodiments;

FIGS. 25 to 27 are schematic diagrams of electronic devices according to various example embodiments;

FIG. 28 is a schematic plan view of a display apparatus manufactured using an apparatus for manufacturing a display apparatus according to some example embodiments; and

FIG. 29 is a schematic cross-sectional view of a display apparatus manufactured by an apparatus for manufacturing a display apparatus according to some example embodiments and may correspond to a cross-section of the display apparatus taken along line XX-XX′ of FIG. 28.

### DETAILED DESCRIPTION

Reference will now be made in detail to some example embodiments, examples of which are illustrated in the accompanying drawings, wherein like reference numerals refer to like elements throughout. In this regard, some example embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to some example embodiments, and particular embodiments will be illustrated in the drawings and described in the detailed description section. The effect and features of some example embodiments, and a method to achieve the same, will be clearer referring to the detailed descriptions below with the drawings. However, some example embodiments may be implemented in various forms, not by being limited to the embodiments presented below.

Hereinafter, some example embodiments will be described, in detail, with reference to the accompanying drawings, and in the description with reference to the drawings, the same or corresponding components are indicated by the same reference numerals and redundant descriptions thereof are omitted.

In the following example embodiments, it will be understood that although the terms “first,” “second,” etc. may be used herein to describe various components, these components should not be limited by these terms. These terms are only used to distinguish one component from another.

In the following example embodiments, the expression of singularity in the specification includes the expression of plurality unless clearly specified otherwise in context.

In the following example embodiments, it will be further understood that the terms “includes,” “has,” “including,” and/or “having” used herein specify the presence of stated features or components, but do not preclude the presence or addition of one or more other features or components.

In the following example embodiments, it will be understood that when a layer, region, or component is referred to as being “formed on” another layer, region, or component, it can be directly or indirectly formed on the other layer, region, or component. That is, for example, intervening layers, regions, or components may be present.

In the following example embodiments, when layers, regions, or components are connected to each other, the layers, the regions, or the components may be directly connected to each other, or another layer, another region, or another component may be disposed between the layers, the regions, or the components and thus the layers, the regions, or the components may be indirectly connected to each other. In addition, when layers, regions, or components are electrically connected to each other, the layers, the regions, or the components may be directly electrically connected to each other, or another layer, another region, or another component may be disposed between the layers, the regions, or the components and thus the layers, the regions, or the components may be indirectly electrically connected to each other.

Sizes of elements in the drawings may be exaggerated or reduced for convenience of explanation. For example, since sizes and thicknesses of components in the drawings are arbitrarily illustrated for convenience of explanation, the following example embodiments are not limited thereto.

In the following example embodiments, the expression such as “A and/or B” may include A, B, or A and B. Furthermore, the expression such as “at least one of A and B” may include A, B, or A and B.

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an objective portion is viewed from above. In addition, “in a cross-sectional view” means that a cross-section of an objective portion taken vertically is viewed from a lateral side. In the following example embodiments, “overlapping” of a first component and a second component means that the first component is located above or below the second component.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain example embodiments may be implemented differently, a specific process order may be performed differently from the described order. For example, two consecutively described processes may be performed substantially at the same time or in an order opposite to the described order.

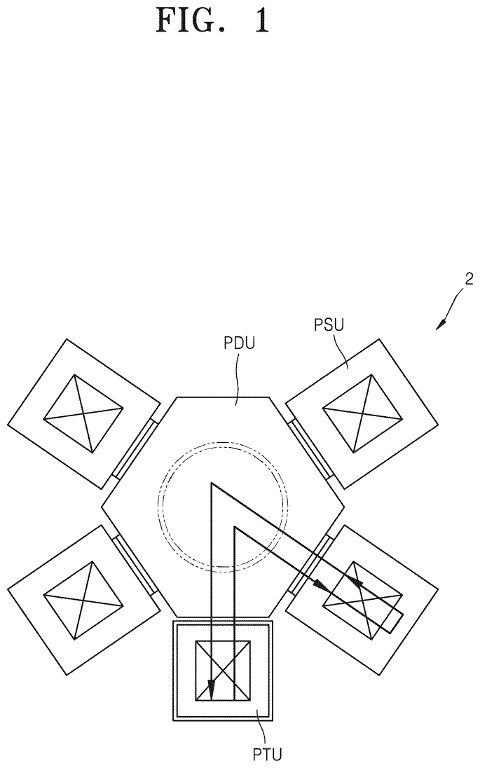

FIG. 1 is a schematic plan view of an apparatus for manufacturing a display apparatus according to some example embodiments.

According to some example embodiments, an apparatus 2 for manufacturing a display apparatus may include an apparatus for pressing a bonding panel BP. The bonding panel BP may refer to a panel including a first panel and a second panel bonded to each other. According to some example embodiments, the first panel may be a display substrate including a pixel circuit, and the second panel may be a touch screen panel including a touch sensor.

A filler may be injected between the first panel and the second panel. According to some example embodiments, the filler may include a resin and may serve as a buffer between the first panel and the second panel, and provide cushioning therebetween. According to some example embodiments, the filler may bond the first panel and the second panel.

The filler is injected to spread evenly to an outer edge of the first panel. Therefore, after injecting the filler between the first panel and the second panel, a waiting process may be performed for a desired (and/or alternatively predetermined) time to allow the filler to spread evenly to the outer edge of the first panel. As a waiting time of the waiting process becomes longer, a process time for manufacturing the display apparatus may become excessively long. According to some example embodiments, the apparatus 2 for manufacturing a display apparatus may press the bonding panel with the filler injected between the first panel and the second panel so that the filler may be evenly spread to outer edges of the bonding panel.

Referring to FIG. 1, according to some example embodiments, the apparatus 2 for manufacturing a display apparatus may include a panel transfer unit PTU, a distribution unit PDU, and a press unit PSU.

The panel transfer unit PTU may accommodate the bonding panel with the filler injected between the first panel and the second panel. The first panel and the second panel may be bonded in another apparatus, the filler may be injected to form the bonding panel, and then, the bonding panel may be transferred to the panel transfer unit PTU. Also, the panel transfer unit PTU may transfer the bonding panel that has been pressed in the press unit PSU to the outside again.

Also, according to some example embodiments, the panel transfer unit PTU may heat-treat the introduced bonding panel. For example, the panel transfer unit PTU may apply heat to the bonding panel to soften the filler between the first panel and the second panel.

The bonding panel may be transferred to the panel transfer unit PTU, heat-treated, and then transferred to the distribution unit PDU. The distribution unit PDU may receive the bonding panel from the panel transfer unit PTU and transfer the bonding panel to one of a plurality of press units PSU. Also, the distribution unit PDU may receive the bonding panels pressed in the plurality of press units PSU again and transfer the bonding panels to the panel transfer unit PTU.

The press unit PSU may be disposed adjacent to the distribution unit PDU. According to some example embodiments, a plurality of press units PSU may be provided, and the plurality of press units PSU may be spaced apart and disposed along a circumference of the distribution unit PDU. As the plurality of press units PSU are provided, more bonding panels may be pressed at an increased rate. According to some example embodiments, the distribution unit PDU may sequentially receive bonding panels from the panel transfer unit PTU and sequentially distribute the bonding panels to the plurality of press units PSU. The bonding panel delivered to the press unit PSU may be pressed. Accordingly, the filler injected between the first panel and the second panel may spread evenly throughout the panel more quickly. The pressed bonding panel may be transferred to the panel transfer unit PTU through the distribution unit PDU again and carried out to the outside.

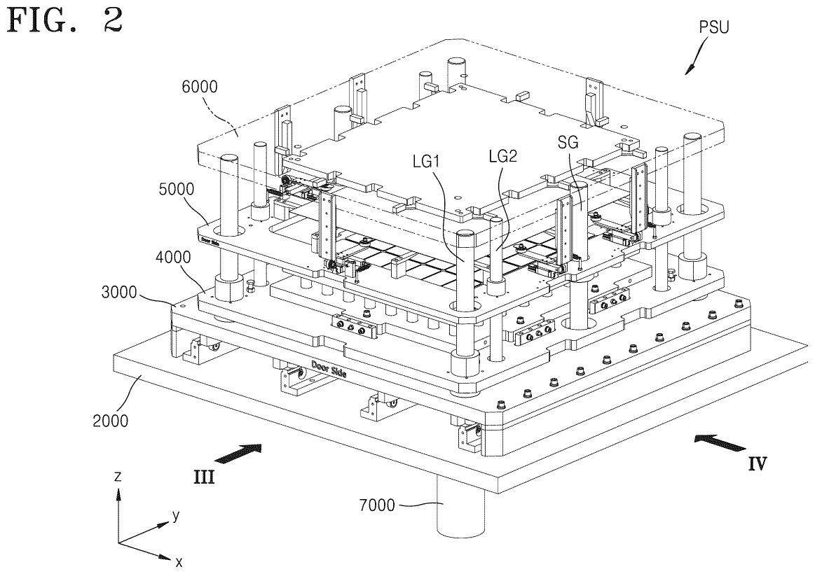

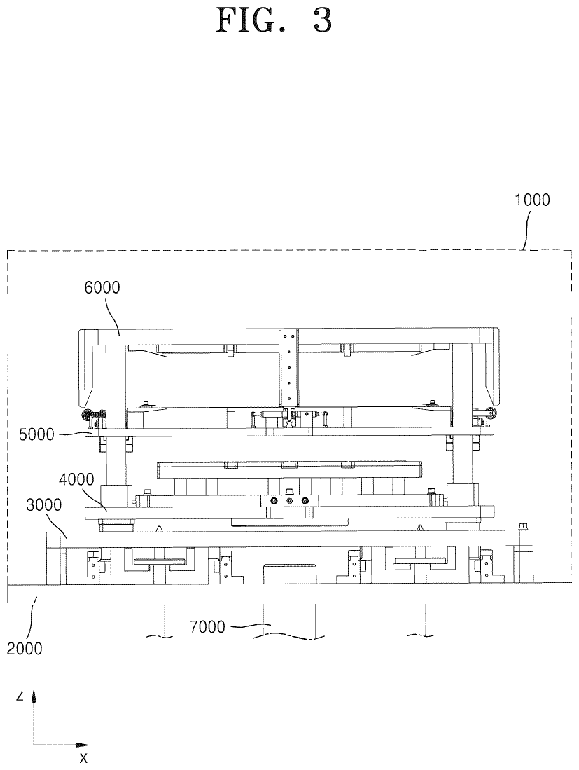

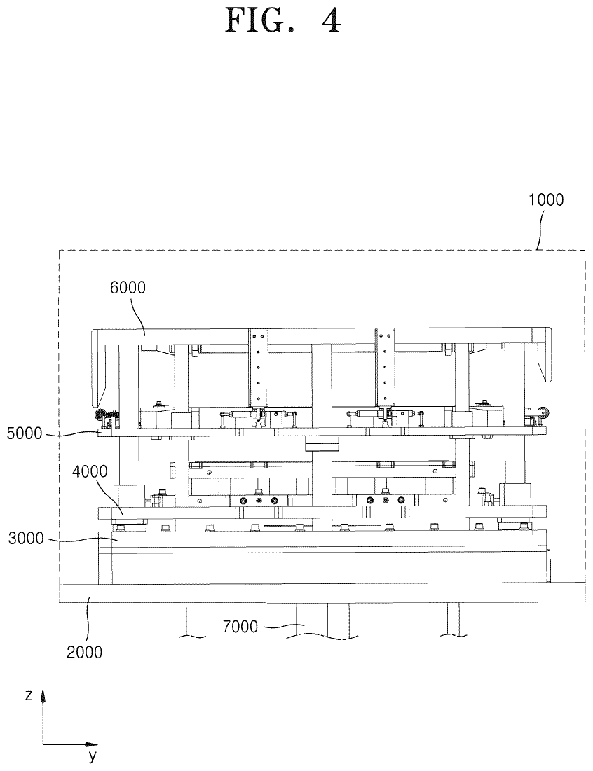

FIG. 2 is a schematic perspective view of a press unit according to some example embodiments. In FIG. 2, a chamber is not shown for convenience of description, and a topmost second base plate and a bottommost fixed stage unit are shown with dotted lines. FIG. 3 is a schematic front view of a press unit according to some example embodiments and may be a view taken in direction III of FIG. 2. FIG. 4 is a schematic side view of a press unit according to some example embodiments, and may be a view taken in direction IV of FIG. 2.

Referring to FIGS. 2 to 4, the press unit PSU may include a chamber 1000, a fixed stage unit 2000, a transfer unit 3000, a first stage unit 4000, a panel receiving unit 5000, a second stage unit 6000, and a cylinder 7000.

The chamber 1000 may have a space formed therein and may accommodate other components of the press unit PSU. In this case, a portion of the chamber 1000 may be formed to be opened, and in this case, the opened portion of the chamber 1000 may be opened or closed by a door. According to some example embodiments, an interior of the chamber 1000 may be in a vacuum state. Accordingly, the press unit PSU may perform a press process in a vacuum state inside the chamber 1000.

The fixed stage unit 2000 is seated in the chamber 1000, and the fixed stage unit 2000 may be fixed to the chamber 1000. The press unit PSU may be guided and moved to the fixed stage unit 2000 through the transfer unit 3000, and may be fixed in the chamber 1000 through coupling of the fixed stage unit 2000 and the transfer unit 3000. The transfer unit 3000 may be guided and moved along a rail provided in the fixed stage unit 2000.

The first stage unit 4000 is disposed on the transfer unit 3000 and may move up and down along a first linear guide LG1. The first stage unit 4000 may be raised to contact the panel receiving unit 5000 and may be raised together with the panel receiving unit 5000.

The panel receiving unit 5000 is disposed on the first stage unit 4000 and may move up and down along a second linear guide LG2. Also, the panel receiving unit 5000 may be stopped by a stop guide SG so as not to descend below a preset height when descending. The panel receiving unit 5000 may accommodate the bonding panel BP. For example, the panel receiving unit 5000 may support the bonding panel BP through a panel holder 5200. The first stage unit 4000 may be raised to contact the panel receiving unit 5000, and the bonding panel BP may contact and be supported by the first stage unit 4000. Also, the first stage unit 4000 and the panel receiving unit 5000 may be raised together toward the second stage unit 6000.

The second stage unit 6000 may be disposed on the panel receiving unit 5000. Th first linear guide LG1, the second linear guide LG2, and the stop guide SG may extend between the second stage unit 6000 and the transfer unit 3000. The second stage unit 6000 may be supported by the first linear guide LG1, the second linear guide LG2, and the stop guide SG. The first stage unit 4000 may be configured to be raised together with the panel receiving unit 5000 and the bonding panel BP, and the bonding panel BP may contact the second stage unit 6000. That is, a lower surface of the bonding panel BP may contact the first stage unit 4000 and an upper surface of the bonding panel BP may contact the second stage unit 6000. The bonding panel BP may be pressed between the first stage unit 4000 and the second stage unit 6000 by the lifting force of the first stage unit 4000. Accordingly, the filler between the first panel and the second panel may spread evenly over an entire surface of the panel.

The cylinder 7000 is formed to penetrate the fixed stage unit 2000 and the transfer unit 3000, and may move in a third direction (for example, z direction), that is, may rise and descend. The cylinder 7000 may be raised to contact the first stage unit 4000 to raise the first stage unit 4000. According to some example embodiments, the cylinder 7000 may be driven by a motor.

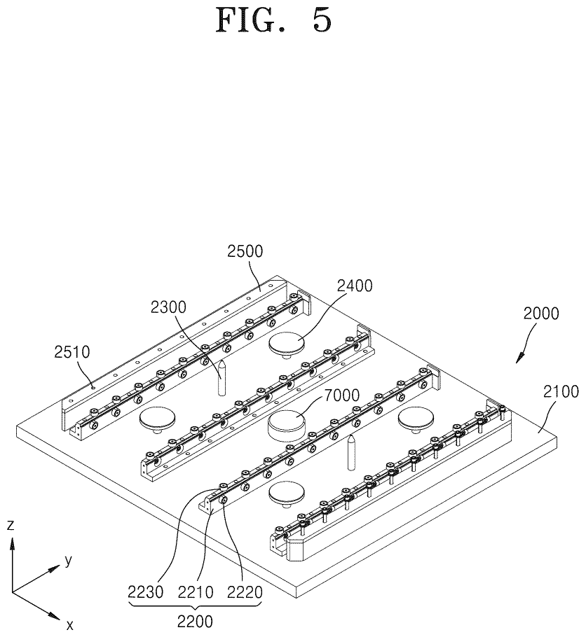

FIG. 5 is a schematic perspective view of a fixed stage unit according to some example embodiments.

Referring additionally to FIG. 5, the fixed stage unit 2000 may include a fixed plate 2100, a guide rail 2200, a fixed pin 2300, a fixed disk 2400, and a fixed bar 2500.

The fixed plate 2100 may be a base plate of the press unit PSU disposed in an internal space of the chamber 1000. According to some example embodiments, the fixed plate 2100 may be seated or fixed to the chamber 1000. Alternatively, according to some example embodiments, the fixed plate 2100 may constitute a bottom plate of the chamber 1000. In this case, the fixed plate 2100 becomes a bottom surface of the chamber 1000, and lateral surfaces and an upper surface of the chamber 1000 may be disposed along a circumference of the fixed plate 2100. According to some example embodiments, the fixed plate 2100 may include a central hole, and the cylinder 7000 may be inserted through the hole.

A guide rail 2200 may be disposed on an upper surface of the fixed plate 2100. According to some example embodiments, a plurality of guide rails 2200 may be provided spaced apart along a first direction (for example, x direction). Each of the plurality of guide rails 2200 may extend long in a second direction (for example, y direction). Although FIG. 5 shows that four guide rails 2200 are provided, the example embodiments are not necessarily limited thereto.

According to some example embodiments, the guide rail 2200 may include a rail 2210, a first bearing 2220, and a second bearing 2230. The rail 2210 extends long in the second direction, and the first bearing 2220 may be disposed on a side surface of the rail 2210. According to some example embodiments, a plurality of first bearings 2220 may be provided, and the plurality of first bearings 2220 may be spaced apart and disposed along the second direction (y direction). The first bearings 2220 may support the transfer unit 3000 disposed on the fixed stage unit 2000 as load bearings. Specifically, the first bearing 2220 may contact a sliding bar 3200 of the transfer unit 3000 and allow the sliding bar 3200 to slide through the first bearings 2220. Also, the first bearing 2220 may support the sliding bar 3200 to support the transfer unit 3000. A second bearing 2230 may be disposed on an upper surface of the rail 2210. According to some example embodiments, a plurality of second bearings 2230 may be provided, and the plurality of second bearings 2230 may be spaced apart and disposed along the second direction (y direction). The second bearings 2230 may guide entry and exit of the transfer unit 3000 as guide bearings. Specifically, the second bearing 2230 may guide the sliding bar 3200 when the sliding bar 3200 slides through the guide rail 2200.

The fixed pin 2300 is a pin penetrating the fixed plate 2100 and may rise and descend. According to some example embodiments, the fixed pin 2300 may be raised and inserted into a pin hole 3400 provided in the transfer unit 3000. The fixed pin 2300 may be a position pin that allows the transfer unit 3000 to be coupled to the fixed stage unit 2000 at a correct position.

The fixed disk 2400 includes a disk pin penetrating the fixed plate 2100 and a disk plate connected to the disk pin, and may rise and descend. According to some example embodiments, the fixed disk 2400 may be lowered and coupled to a bracket 3300 provided in the transfer unit 3000. As the fixed disk 2400 and the bracket 3300 of the transfer unit 3000 are coupled, the transfer unit 3000 may be fixed to the fixed stage unit 2000. According to some example embodiments, the fixed disk 2400 may be driven by pneumatic pressure, but the example embodiments are not necessarily limited thereto.

The fixed bars 2500 may be disposed on both sides of the fixed plate 2100 in the first direction (x direction). According to some example embodiments, the fixed bar 2500 may extend in the second direction (y direction) and include a plurality of fixing holes 2510. After the transfer unit 3000 is seated on the fixed stage unit 2000, bolts may be fastened to the fixing holes 2510 so that the fixed bar 2500 is coupled with the transfer unit 3000.

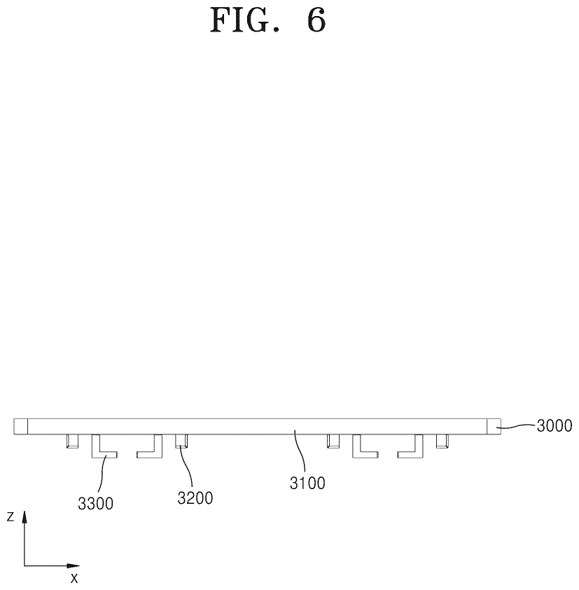

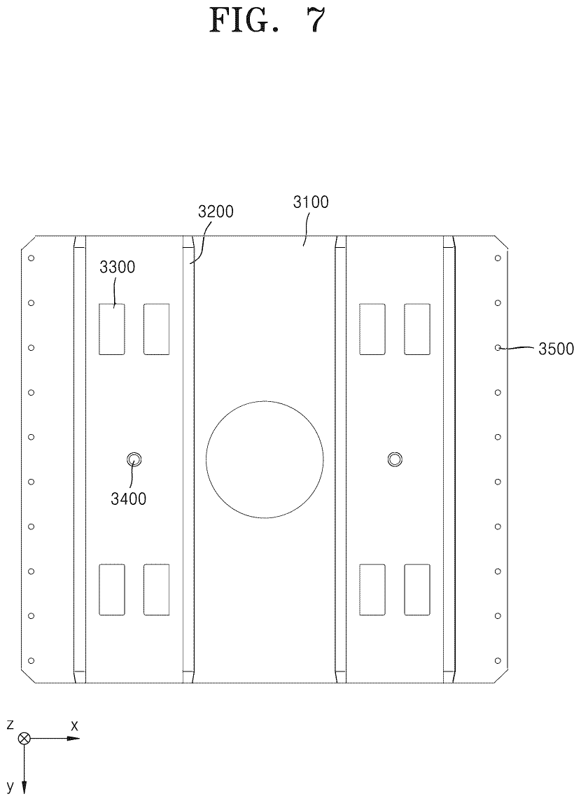

FIG. 6 is a schematic front view of a transfer unit according to some example embodiments. FIG. 7 is a schematic bottom view of a transfer unit according to some example embodiments.

Referring to FIGS. 6 and 7, the transfer unit 3000 may be slid and moved to the fixed stage unit 2000. According to some example embodiments, the transfer unit 3000 may include a transfer plate 3100 and a sliding bar 3200.

The transfer plate 3100 may be disposed spaced apart from the fixed plate 2100 on the fixed stage unit 2000, for example, the fixed plate 2100. According to some example embodiments, the transfer plate 3100 may include a central hole, and the cylinder 7000 may be inserted through the hole to rise and descend.

A sliding bar 3200 may be disposed on a lower surface of the transfer plate 3100. According to some example embodiments, a plurality of sliding bars 3200 may be provided spaced apart along a first direction (for example, x direction). Each of the plurality of sliding bars 3200 may extend long in a second direction (for example, y direction). It will be understood that a number of sliding bars 3200 may be provided to correspond to a number of guide rails 2200. Although FIG. 7 shows that four sliding bars 3200 are provided, the example embodiments are not necessarily limited thereto.

The sliding bar 3200 may be slid and moved along the guide rail 2200 as described above. Specifically, the press unit PSU may be transferred into the chamber 1000 or from the chamber 1000 to the outside. In this case, the press unit PSU may be easily transferred by the sliding bar 3200 and the guide rail 2200.

Also, a bracket 3300 may be provided on a lower surface of the transfer plate 3100. The bracket 3300 may be disposed between the plurality of sliding bars 3200. The bracket 3300 may be fastened with the fixed disk 2400 as described above. According to some example embodiments, the bracket 3300 may be disposed to surround both sides of the fixed disk 2400. For example, the bracket 3300 may be disposed on both sides of the fixed disk 2400, respectively, and may be provided in an approximately ‘L’ shape in a front view to support the fixed disk 2400. Also, a pin hole 3400 may be provided on a lower surface of the transfer plate 3100. The pin hole 3400 is a hole into which the fixed pin 2300 is inserted as described above, and may facilitate alignment of the transfer plate 3100 and the fixed plate 2100.

A plurality of corresponding holes 3500 may be disposed at both ends of the transfer plate 3100 in the first direction (x direction). The corresponding hole 3500 may be a hole corresponding to the fixing hole 2510 of the fixed bar 2500 disposed on the fixed plate 2100. After the fixed pin 2300 is inserted into the pin hole 3400 to fix positions of the transfer plate 3100 and the fixed plate 2100, the fixing hole 2510 and the corresponding hole 3500 corresponding thereto are aligned, and then bolts may be fastened. Accordingly, the transfer plate 3100 may be firmly fixed to the fixed plate 2100.

Also, referring to FIG. 2 together, a first linear guide LG1, a second linear guide LG2, and a stop guide SG may be disposed on an upper surface of the transfer plate 3100.

According to some example embodiments, four first linear guides LG1 may be provided and respectively disposed at corners of the transfer plate 3100. The first linear guide LG1 may be a shaft extending in a third direction (for example, z direction). The first linear guide LG1 may guide ascending or descending movement of the first stage unit 4000.

According to some example embodiments, four second linear guides LG2 may be provided and may be disposed adjacent to the first linear guide LG1. The second linear guide LG2 may be a shaft extending in a third direction (for example, z direction). The second linear guide LG2 may guide ascending or descending movement of the panel receiving unit 5000.

According to some example embodiments, two stop guides SG may be provided and respectively disposed on both sides of the transfer plate 3100. The stop guide SG may be a shaft extending in a third direction (for example, z direction). The stop guide SG may include a protrusion in a middle of the shaft and may function as a stopper when the panel receiving unit 5000 descends.

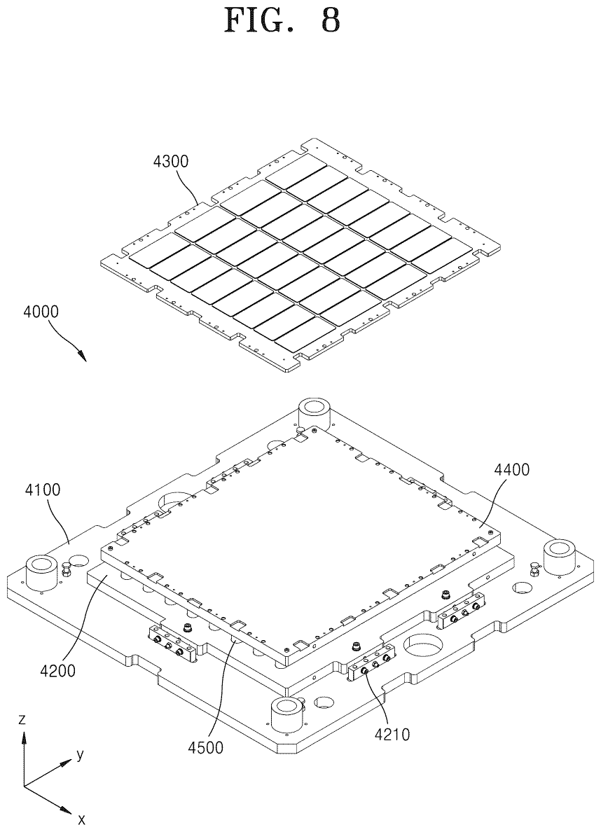

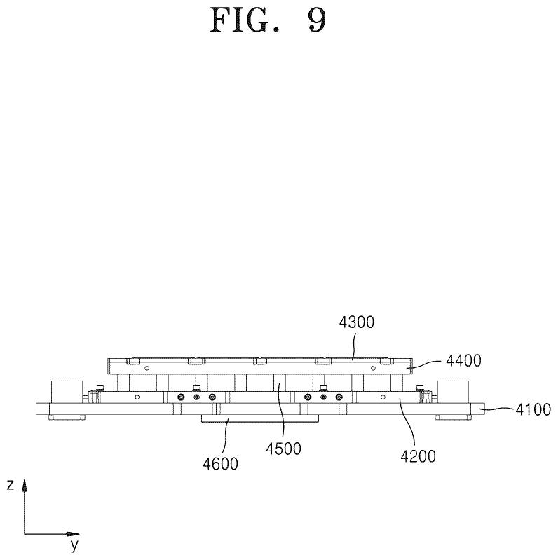

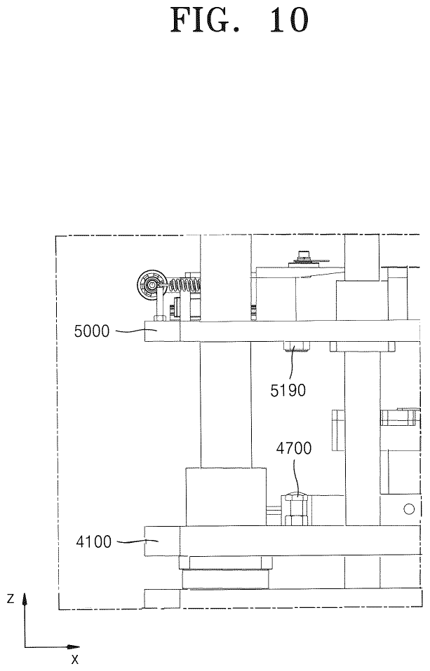

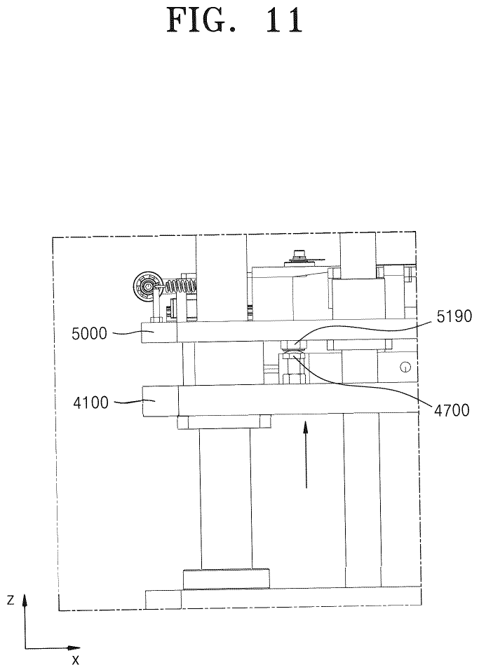

FIG. 8 is a schematic perspective view of a first stage unit according to some example embodiments. FIG. 9 is a schematic side view of a first stage unit according to some example embodiments. FIGS. 10 and 11 are enlarged views of portion X of FIG. 9.

Referring to FIGS. 8 and 9, the first stage unit 4000 may include a first base plate 4100, a load plate 4600, an adjustment plate 4200, a first stage 4300, a first sub-stage 4400, and a support column 4500.

The first base plate 4100 is disposed on the transfer unit 3000 and may be disposed spaced apart from the transfer plate 3100 by a preset distance by a stopper provided on an upper surface of the transfer plate 3100. A lifting force of the cylinder 7000 may be transmitted to the first base plate 4100 through the load plate 4600. According to some example embodiments, the first base plate 4100 may include a heater. The heater may heat the entire first stage unit 4000 through the first base plate 4100. Accordingly, as will be described below, a lower portion of the bonding panel BP may be heated by the first stage unit 4000 so that the filler may spread more easily.

The load plate 4600 may be disposed below the first base plate 4100. According to some example embodiments, the load plate 4600 may be disposed at a center of the first base plate 4100 and may have a smaller size than the first base plate 4100. The load plate 4600 is a plate that directly contacts the cylinder 7000, contacts the ascending cylinder 7000, and may transmit a lifting force of the cylinder 7000 upward.

The adjustment plate 4200 may be disposed on the first base plate 4100. Alignment of the adjustment plate 4200 may be finely adjusted by adjustment bolts 4210 disposed at each edge. Accordingly, a stage disposed on the adjustment plate 4200 may be finely adjusted. According to some example embodiments, the adjustment bolt 4210 may include a push bolt and a pull bolt.

The first stage 4300 may be disposed spaced apart from the adjustment plate 4200 on the adjustment plate 4200. When the cylinder 7000 is raised and the first stage unit 4000 is raised, the first stage 4300 may be a portion that contacts a lower surface of the bonding panel BP. A first sub-stage 4400 may be disposed below the first stage 4300. The first sub-stage 4400 may support the first stage 4300 and may distribute and transmit a lifting force by the cylinder 7000 to the first stage 4300.

A support column 4500 may be disposed between the first stage 4300 and the first sub-stage 4400 and the adjustment plate 4200. A plurality of support columns 4500 may be provided and may connect between the first sub-stage 4400 and the adjustment plate 4200. The support columns 4500 may distribute a lifting force by the cylinder 7000 and transmit the lifting force to the first stage 4300. According to some example embodiments, the plurality of support columns 4500 may be spaced apart and disposed in a first direction (x direction) and a second direction (y direction), and may be arranged in a lattice form, for example.

FIGS. 10 and 11 are schematic side views of a stopper unit 4700 disposed on the first base plate 4100. Referring to FIGS. 10 and 11, a stopper unit 4700 may be disposed on the first base plate 4100. According to some example embodiments, the stopper units 4700 may be respectively disposed at corners of the first base plate 4100. As shown in FIGS. 10 and 11, the stopper unit 4700 may contact the panel receiving unit 5000, for example, a stopper contact unit 5190 provided in the panel receiving unit 5000, when the first stage unit 4000 is raised by the cylinder 7000. Accordingly, when the first stage unit 4000 continuously rises by the cylinder 7000, the panel receiving unit 5000 may also rise together with the first stage unit 4000. According to some example embodiments, a height of the stopper unit 4700 may be adjusted by a bolt, and accordingly, a contact position with the panel receiving unit 5000 may be finely adjusted.

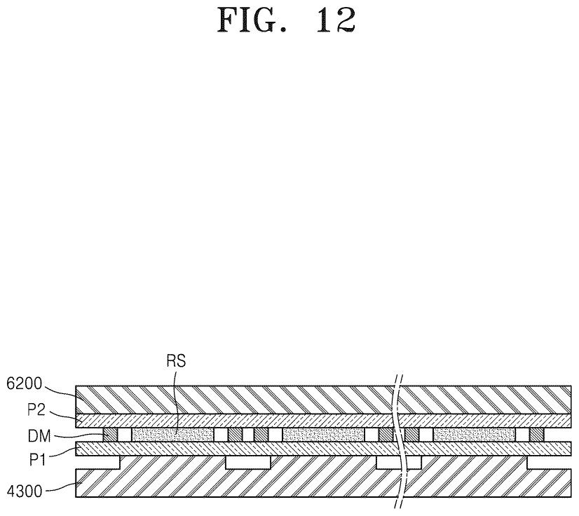

FIG. 12 is a schematic cross-sectional view of a first stage according to some example embodiments. FIG. 12 shows only the first stage 4300, the bonding panel BP, and the second stage 6200 for convenience of description.

Referring to FIGS. 12 and 8, the first stage 4300 may include a protrusion 4310. The protrusion 4310 may be a portion protruding in a third direction (z direction), that is, upward from an upper surface of the first stage 4300. According to some example embodiments, a size of the protrusion 4310 in a plan view may be less than a size of a cell. The bonding panel BP may be a mother panel to be cut into a plurality of cell units. That is, the bonding panel BP may be cut to form a plurality of cells after a process is completed. In this case, a filler RS may be disposed inside a cell area between the first panel P1 and the second panel P2, and a dam unit DM may be disposed around the cell area.

In this case, the protrusion 4310 may have a smaller size than the cell area, and may be disposed inside the dam unit DM disposed around the cell area of the bonding panel BP in a plan view, for example. In other words, the protrusion 4310 may be disposed to be surrounded by the dam unit DM in a plan view. Also, according to some example embodiments, the protrusion 4310 may have a smaller size than the cell area and a larger size than the filler RS in a plan view.

Also, when the bonding panel BP includes a plurality of cell areas, it will be understood that the protrusions 4310 may also be provided in a number corresponding to a number of cell areas. As the first stage 4300 includes the protrusion 4310, the first stage 4300 may more efficiently transmit a pressing force to the filler RS in a press process through the first stage 4300 and the second stage 6200.

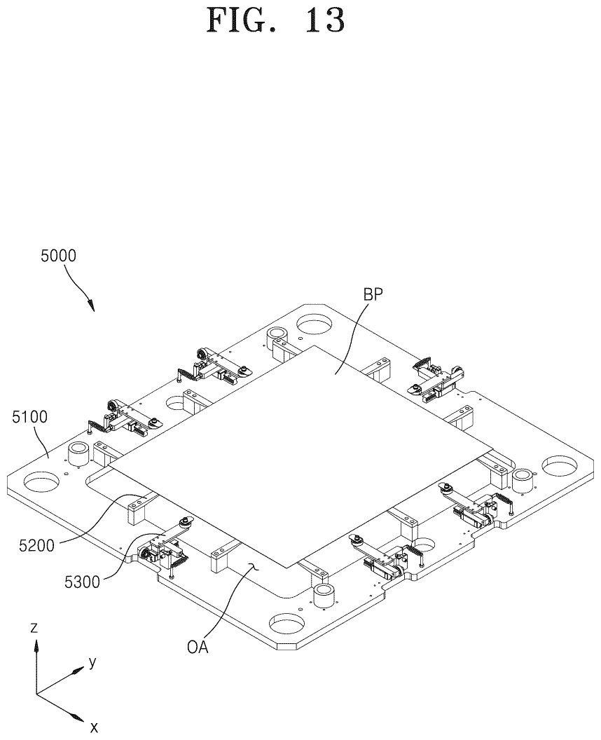

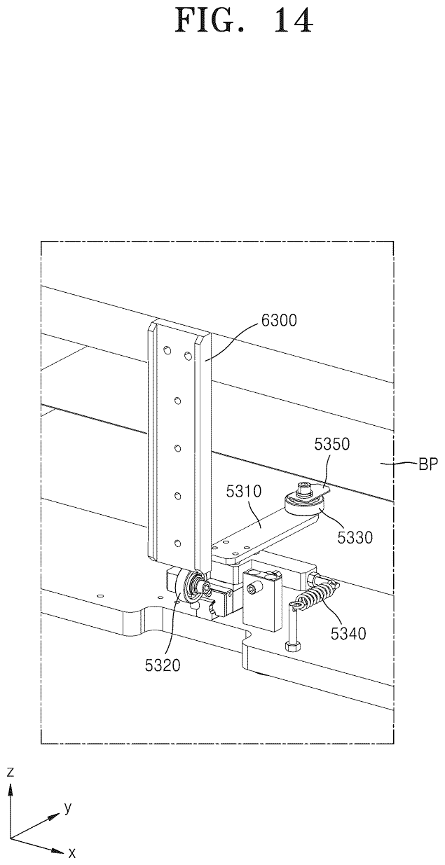

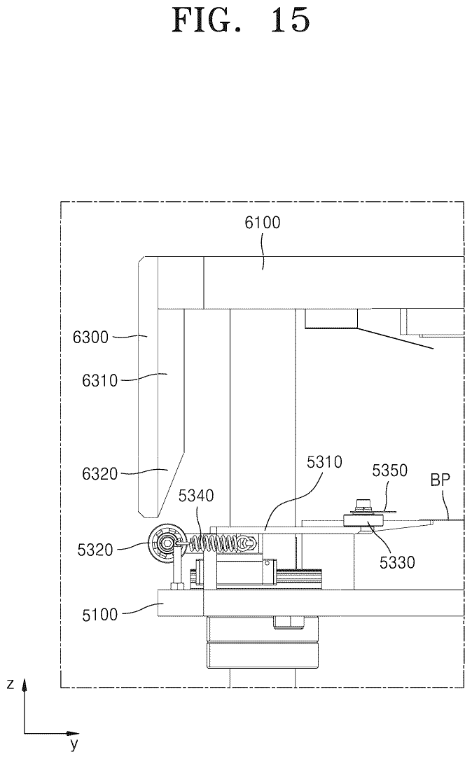

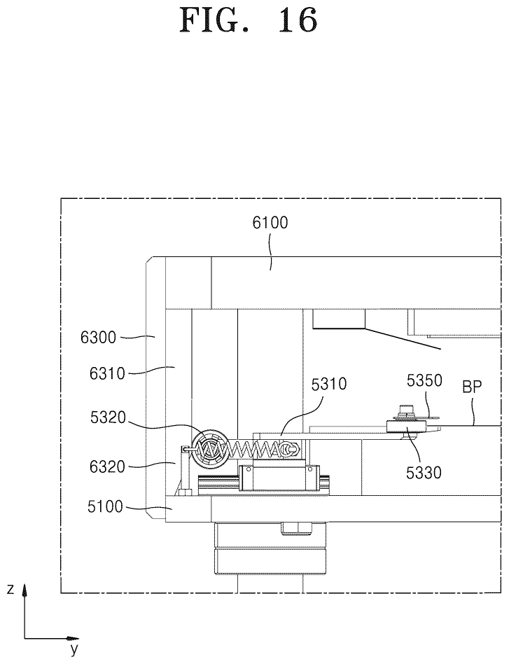

FIG. 13 is a schematic perspective view of a panel receiving unit according to some example embodiments. FIG. 14 is a schematic perspective view of a panel adjustment unit according to some example embodiments, and is an enlarged view of portion XIV of FIG. 13. FIGS. 15 and 16 are schematic front views of a panel adjustment unit according to some example embodiments, and show an operation of the panel adjustment unit.

Referring to FIGS. 13 to 16, the panel receiving unit 5000 may accommodate the bonding panel BP. According to some example embodiments, the panel receiving unit 5000 may be disposed on the first stage unit 4000. As shown in FIG. 13, the bonding panel BP may be loaded into the panel receiving unit 5000 from outside by a robot arm or a transfer rail. According to some example embodiments, the panel receiving unit 5000 may include a frame 5100, a panel holder 5200, and a panel adjustment unit 5300.

The frame 5100 has an opening area OA at a center, and may be a rectangular frame according to some example embodiments. When the first stage unit 4000 is raised, a circumference of the first base plate 4100 of the first stage unit 4000 contacts the frame 5100, and since the first stage 4300 is formed to protrude upward from the first base plate 4100, the first stage 4300 may be positioned to penetrate the opening area OA. Accordingly, the bonding panel BP supported by the panel holder 5200 may contact the first stage 4300.

The panel holders 5200 are disposed on the frame 5100 and may be spaced apart and disposed in plurality along a circumference of the frame 5100. According to some example embodiments, the panel holder 5200 may have a plate form for supporting a lower surface of the bonding panel BP. Although FIG. 13 shows that ten panel holders 5200 are provided, the example embodiments are not necessarily limited thereto. For example, it will be understood that the panel holders 5200 may be provided in ten or fewer, or ten or more.

The panel adjustment unit 5300 may adjust and align a position of the bonding panel BP supported by the panel holder 5200. The panel adjustment units 5300 are disposed on the frame 5100 and may be spaced apart and disposed in plurality along a circumference of the frame 5100. According to some example embodiments, the panel adjustment units 5300 may be alternately disposed with the panel holders 5200. Although FIG. 13 shows that six panel adjustment units 5300 are provided, the example embodiments are not necessarily limited thereto. For example, it will be understood that the panel adjustment units 5300 may be provided in six or fewer, or six or more.

According to some example embodiments, the panel adjustment unit 5300 may include a moving plate 5310, a cam bearing 5320, an alignment bearing 5330, and an elastic unit 5340.

The moving plate 5310 is disposed on the frame 5100 and may linearly move such as advancing or retreating toward an inner side of the frame 5100, for example, the opening area OA. According to some example embodiments, the moving plate 5310 may include a movement guide between the moving plate 5310 and the frame 5100. The movement guide may include, for example, a linear motor, and accordingly, the moving plate 5310 may move linearly through the movement guide.

A cam bearing 5320 may be disposed at one end of the moving plate 5310, for example, an outer end facing outside. As shown in FIGS. 15 and 16, the cam bearing 5320 may rise along an inclined portion of the cam 6300 as the panel receiving unit 5000 is raised by a lifting force. In this case, the cam bearing 5320 may be pushed inward by the inclined portion of the cam 6300, and accordingly may move the moving plate 5310 inward. Accordingly, the panel adjustment unit 5300 may move toward the bonding panel BP to contact an edge of the bonding panel BP and align the bonding panel BP. Also, as the panel receiving unit 5000 is raised, the plurality of cam bearings 5320 and moving plates 5310 may move simultaneously. Also, by adjusting an angle of the inclined portion of the cam 6300, a speed and amount of movement of the moving plate 5310 may be simply adjusted. Accordingly, alignment of the bonding panel BP may be optimized by adjusting a movement speed and amount of movement of each of the plurality of panel adjustment units 5300.

An alignment bearing 5330 may be disposed at another end of the moving plate 5310, for example, an inner end facing the opening area OA. The alignment bearing 5330 may roll contact an edge of the bonding panel BP.

According to some example embodiments, an auxiliary separation unit 5350 may be disposed on the alignment bearing 5330. After the first stage unit 4000 is pressed toward the second stage unit 6000 and the bonding panel BP is pressed, the bonding panel BP may be removed from the second stage unit 6000. In this case, the bonding panel BP may be removed from the second stage unit 6000 by a panel separation unit 6400 provided in the second stage unit 6000. The auxiliary separation unit 5350 may forcibly separate the bonding panel BP from the second stage unit 6000 when the bonding panel BP is not separated by the panel separation unit 6400.

The elastic unit 5340 may allow the moving plate 5310 to return by elastic force. According to some example embodiments, the elastic unit 5340 may be connected to the moving plate 5310 or the movement guide. When the panel receiving unit 5000 is raised and the moving plate 5310 moves toward the opening area OA, the elastic unit 5340 may be stretched. In this case, tensile elastic force may be acting on the elastic unit 5340. Also, when the panel receiving unit 5000 descends, the moving plate 5310 may return to an original position by the tensile elastic force.

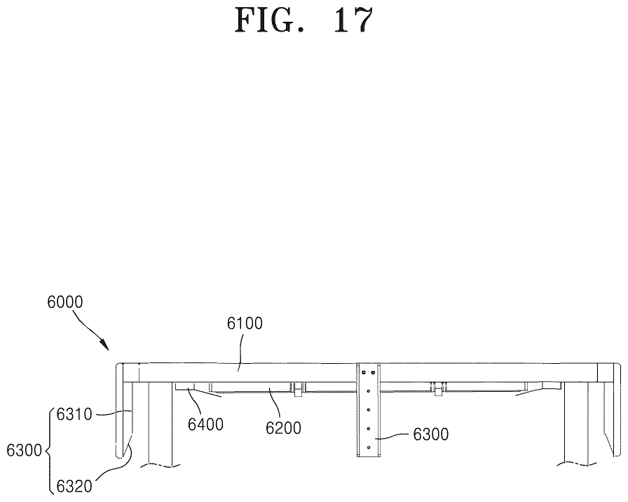

FIG. 17 is a schematic front view of a second stage unit according to some example embodiments.

Referring to FIG. 17, the second stage unit 6000 may be disposed on the panel receiving unit 5000. As described above, the second stage unit 6000 may be supported by the first linear guide LG1, the second linear guide LG2, and the stop guide SG, and may be in a fixed position.

According to some example embodiments, the second stage unit 6000 may include a second base plate 6100, a second stage 6200, a cam 6300, and a panel separation unit 6400.

The second base plate 6100 may be disposed at a topmost portion of the press unit PSU. One ends of the first linear guide LG1, the second linear guide LG2, and the stop guide SG may be connected to the second base plate 6100. According to some example embodiments, the second base plate 6100 may include a heater. The heater may heat the entire second stage unit 6000 through the second base plate 6100. Accordingly, as will be described below, an upper portion of the bonding panel BP may be heated by the second stage unit 6000 so that the filler may spread more easily.

A second stage 6200 may be disposed below the second base plate 6100. When the cylinder 7000 is raised and the bonding panel BP is pressed by the first stage unit 4000 and the second stage unit 6000, the second stage 6200 may be a portion that contacts an upper surface of the bonding panel BP. According to some example embodiments, the second stage 6200 may have a flat plane. For example, a surface of the second stage 6200 that contacts an upper surface of the bonding panel BP may be a flat plane. Accordingly, the second stage 6200 may cooperate with the first stage 4300 to facilitate pressing of the bonding panel BP.

The cam 6300 may be disposed to extend downward from the second base plate 6100. The cam 6300 may be disposed around the second base plate 6100. For example, a plurality of cams 6300 may be spaced apart and disposed along a circumference of the second base plate 6100. The cams 6300 may be provided in a number corresponding to a number of panel adjustment units 5300. Also, according to some example embodiments, the cam 6300 may be positioned on a vertical movement path of the cam bearing 5320.

The cam 6300 may cooperate with the panel adjustment unit 5300 so that the bonding panel BP is aligned as described above. Specifically, the cam 6300 may include a flat portion 6310 and an inclined portion 6320. The flat portion 6310 may be a portion extending downward from the second base plate 6100. According to some example embodiments, the flat portion 6310 may extend in a vertical direction with respect to the second base plate 6100, and accordingly, an inner surface of the flat portion 6310 may have a flat plane perpendicular to the second base plate 6100. The inclined portion 6320 may be a portion extending to have an inclination downward from the flat portion 6310. According to some example embodiments, the inclined portion 6320 may extend to taper in a vertical direction with respect to the second base plate 6100, and accordingly, an inner surface of the inclined portion 6320 may have an inclined surface that is inclined with respect to the second base plate 6100.

As described above, as the panel adjustment unit 5300 rises, the cam bearing 5320 rises along the inner surface of the inclined portion 6320, and accordingly, the moving plate 5310 moves inward so that the panel adjustment unit 5300 advances and may align a circumference of the bonding panel BP. Also, when the panel adjustment unit 5300 continues to rise and the cam bearing 5320 reaches the inner surface of the flat portion 6310, the moving plate 5310 may be fixed without moving inward anymore. According to some embodiments of the disclosure, except for one driving unit for driving ascending of the cylinder 7000, other driving units may not be required. That is, due to ascending of the cylinder 7000, mechanical linkage may operate to perform alignment of the bonding panel BP and pressing of the bonding panel BP.

The panel separation unit 6400 may be disposed on a lower surface of the second base plate 6100. According to some example embodiments, a plurality of panel separation units 6400 may be provided, and the plurality of panel separation units 6400 may be spaced apart and disposed along a circumference of the second stage 6200. According to some example embodiments, the panel separation unit 6400 may include a leaf spring, and may separate the bonding panel BP contacted to the second stage 6200 from the second stage 6200.

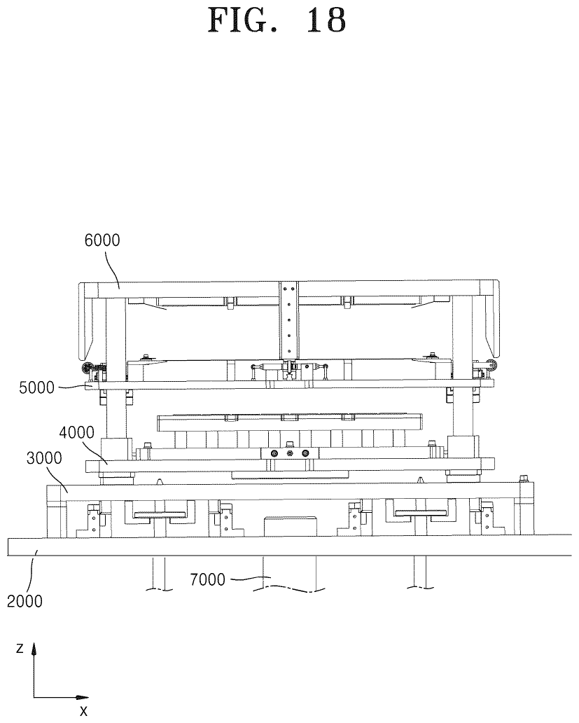

FIGS. 18 to 23 are schematic views of a method for manufacturing a display apparatus according to some example embodiments. The method for manufacturing a display apparatus according to some example embodiments may use the above-described apparatus for manufacturing a display apparatus, but is not necessarily limited thereto.

Referring to FIG. 18, the bonding panel BP may be loaded into the press unit PSU. As described above, the bonding panel BP may be loaded into the chamber 1000 of the press unit PSU by a robot arm or a transfer rail. The chamber 1000 may be in a vacuum state. In this case, the cylinder 7000 may be in a non-driven state. According to some example embodiments, the bonding panel BP may be a panel including a first panel, a second panel, and a filler interposed between the first panel and the second panel. The press unit PSU may press the bonding panel BP so that the filler between the first panel and the second panel spreads evenly.

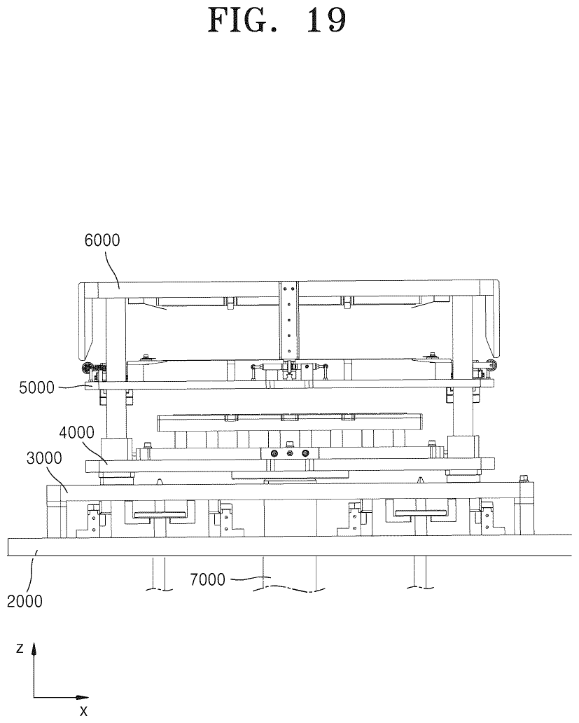

Referring to FIG. 19, the cylinder 7000 may be driven. According to some example embodiments, the cylinder 7000 may be driven by a servo motor or the like. Accordingly, the cylinder 7000 may be raised. The raised cylinder 7000 may contact the first stage unit 4000, for example, the load plate 4600. As the cylinder 7000 continues to rise, the first stage unit 4000 may rise along the first linear guide LG1. Also, at this time, according to some example embodiments, the first stage unit 4000 may heat a lower portion of the bonding panel BP.

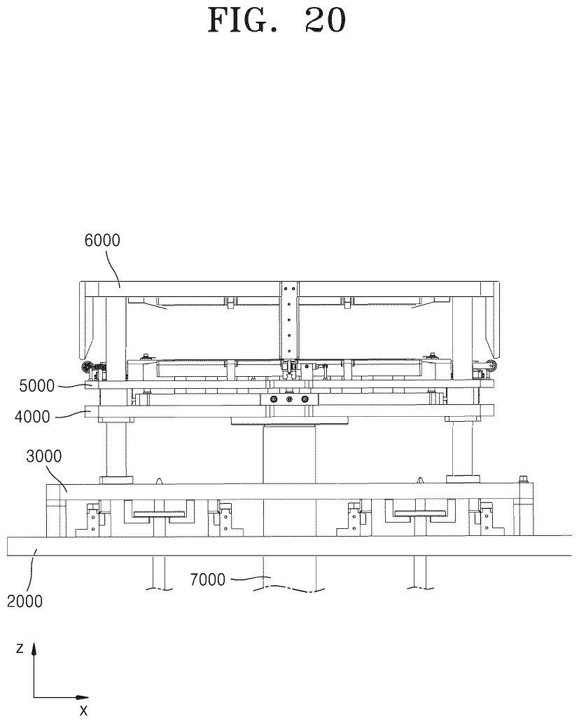

Referring to FIG. 20, the cylinder 7000 may continue to rise so that the first stage unit 4000 may contact the panel receiving unit 5000. In this case, as described above, the stopper unit 4700 of the first base plate 4100 may contact the frame 5100. Also, at this time, the first stage 4300 disposed to protrude from a center of the first base plate 4100 may pass through the opening area OA of the frame 5100 and contact the bonding panel BP supported by the panel holder 5200.

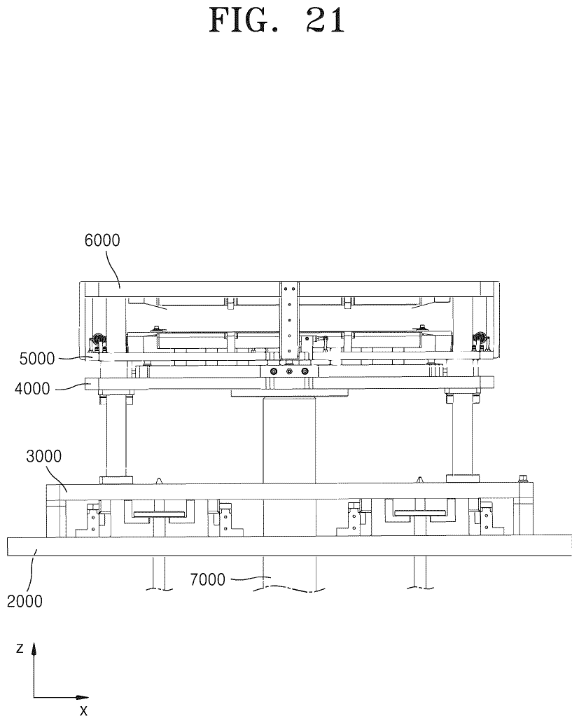

Referring to FIG. 21, the cylinder 7000 may continue to rise so that the first stage unit 4000 and the panel receiving unit 5000 may rise together toward the second stage unit 6000. In this case, as the panel receiving unit 5000 rises, the cam bearing 5320 of the panel adjustment unit 5300 and the cam 6300 provided in the second stage unit 6000 may interact. Accordingly, the bonding panel BP may be aligned in a first direction (x direction) and a second direction (y direction) simultaneously with the rising of the panel receiving unit 5000.

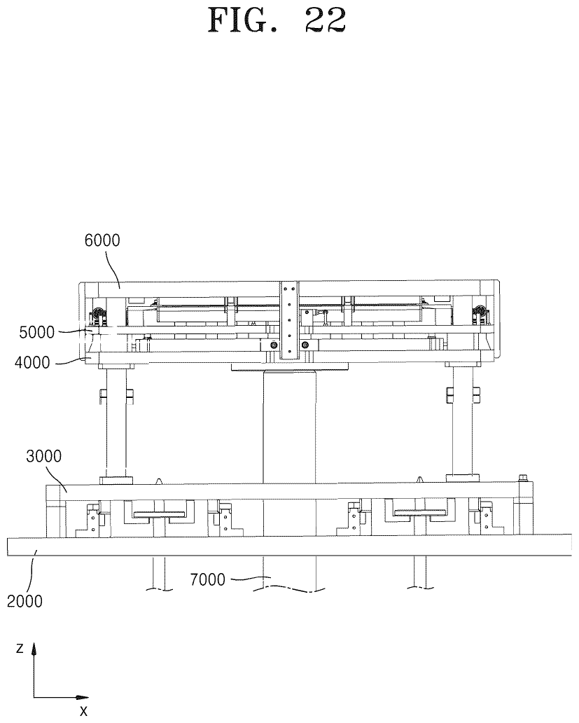

Referring to FIG. 22, the cylinder 7000 may continue to rise so that the bonding panel BP accommodated in the panel receiving unit 5000 may contact the second stage unit 6000. Accordingly, an upper surface of the bonding panel BP may contact the second stage 6200 and a lower surface of the bonding panel BP may contact the first stage 4300, and the bonding panel BP may be pressed by a lifting force of the cylinder 7000. Also, at this time, according to some example embodiments, an upper surface of the bonding panel BP may be heated by the second stage unit 6000. As the bonding panel BP is pressed, the filler interposed between the first panel and the second panel may spread evenly throughout the panel. According to some example embodiments of the disclosure, as the cylinder 7000 is driven, other components may be mechanically interlocked and operated, and accordingly, panel alignment and pressing may be performed by one driving unit. Since an interior of the chamber 1000 of the press unit PSU is maintained in a vacuum state, when there are many driving units, leakage of working fluid and the like may occur. According to some example embodiments of the disclosure, components of the press unit PSU may operate more excellently in a vacuum environment because the components operate by mechanical interlocking operation.

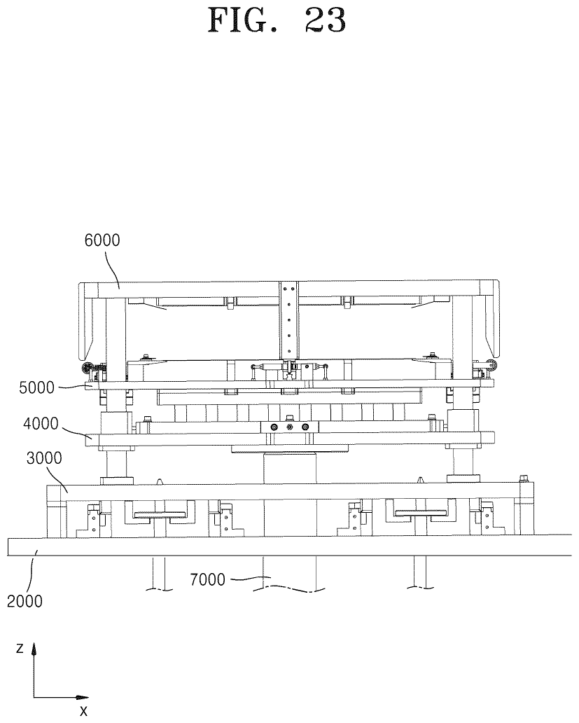

Referring to FIG. 23, after pressing of the bonding panel BP is completed, the cylinder 7000 may descend. Accordingly, the panel receiving unit 5000 and the first stage unit 4000 may descend together. Also, as the panel receiving unit 5000 descends, the panel adjustment unit 5300 that had advanced may also return. Next, the bonding panel BP may be carried out to outside of the chamber 1000, and another new bonding panel BP may be loaded. Next, processes of FIGS. 20 to 23 may be repeated.

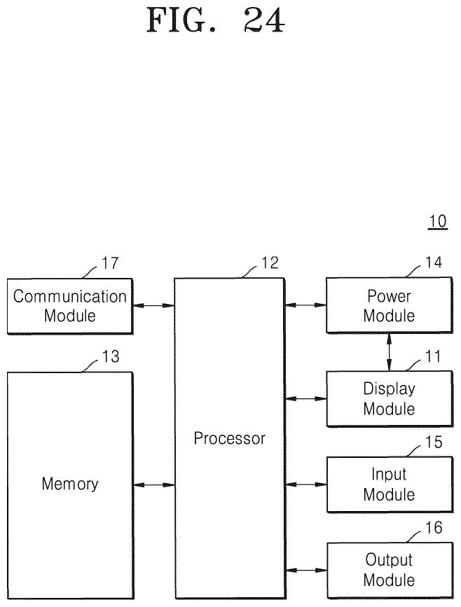

FIG. 24 is a block diagram of an electronic device according to some example embodiments.

Referring to FIG. 24, an electronic device 10 may include a display module 11, a processor 12, a memory 13, and a power module 14. According to some example embodiments, the display module 11 may be manufactured through the above-described apparatus 2 for manufacturing a display apparatus.

The processor 12 may include at least one of a central processing unit (CPU), an application processor (AP), a graphics processing unit (GPU), a communication processor (CP), an image signal processor (ISP), and a controller. According to some example embodiments, the processor 12 may be provided by being divided into two or more from a functional or structural perspective. For example, the processor 12 may include a main processor in a form of a first driving chip including a central processing unit, and an auxiliary processor in a form of a second driving chip including a controller that receives an image signal from the main processor and processes the image signal to conform to interface specifications of the display module 11.

The memory 13 may include at least one of a non-volatile memory and a volatile memory. Data information necessary for operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts power supplied by the power supply module to generate power necessary for operation of the electronic device 10. Power conversion by the power conversion module may include DC-DC conversion, AC-DC conversion, and DC-AC conversion, but example embodiments are not limited thereto.

The electronic device 10 may further include an input module 15, a non-image output module 16, and/or a communication module 17.

The input module 15 may provide input information to the processor 12 and/or the display module 11. The input module 15 may include physical buttons, keyboards, microphones, as well as various sensor modules. Examples of sensor modules may include touch sensors, pressure sensors, distance sensors, position sensors, digitizers, motion recognition sensors, camera sensors, light receiving sensors, photoelectric conversion sensors, temperature sensors, as well as biometric sensors such as blood pressure sensors, blood glucose sensors, electrocardiogram sensors, and heart rate sensors. However, example embodiments are not limited thereto.

The non-image output module 16 may receive information other than images transmitted from the processor 12 and provide the information to a user. Examples of the non-image output module 16 may include an audio module, a haptic module, a light-emitting module, and may include other function modules unique to electronic devices (for example, a cooling module of a refrigerator). However, example embodiments are not limited thereto.

The communication module 17 is a module responsible for transmitting and receiving information between the electronic device 10 and an external device, and may include a receiving unit and a transmitting unit. The communication module 17 may include various wireless communication modules such as a mobile communication module, a Wi-Fi module, and a Bluetooth module, or various wired communication modules. However, example embodiments are not limited thereto.

At least one of the components of the electronic device 10 described above may be included in the display apparatus. Also, among individual modules functionally included in one module, some may be included in the display apparatus and others may be provided separately from the display apparatus. For example, the display apparatus may include the display module 11, and the processor 12, the memory 13, and the power module 14 may be provided in a form of other devices in the electronic device 10 other than the display apparatus. As another example, the power module 14 may be provided in the display apparatus and may supply power to the processor 12 and the memory 13 provided in the electronic device 10 other than the display apparatus, but example embodiments are not limited to the above examples.

The display apparatus may be manufactured by the apparatus 2 for manufacturing a display apparatus described above according to some example embodiments.

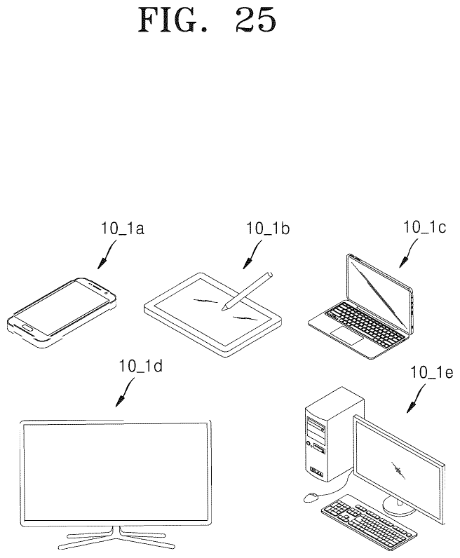

FIGS. 25 to 27 are schematic diagrams of electronic devices according to various example embodiments. FIGS. 25 to 27 show examples of various electronic devices to which display apparatuses according to some example embodiments are applied.

FIG. 25 shows a smartphone 10_1a, a tablet PC 10_1b, a laptop 10_1c, a TV 10_1d, and a desktop monitor 10_1e as examples of electronic devices.

The smartphone 10_1a may include an input module such as a touch sensor and a communication module in addition to the display module 11. The smartphone 10_1a may process information received through a communication module or other input modules and display the information through the display module 11 of the display apparatus.

In cases of the tablet PC 10_1b, laptop 10_1c, TV 10_1d, and desktop monitor 10_1e, similar to the smartphone 10_1a, a display module and an input module are included, and in some cases, a communication module may be further included.

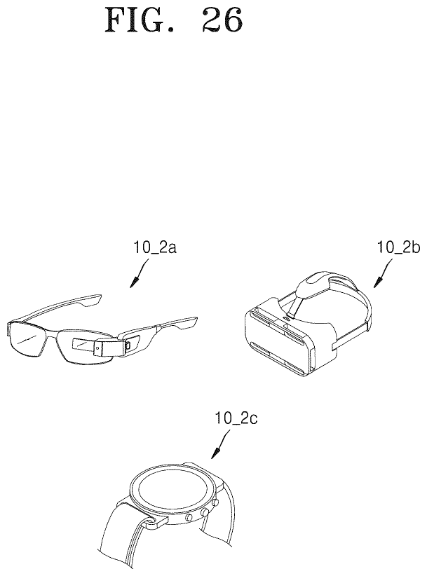

FIG. 26 illustrates a case where an electronic device including a display module is applied to a wearable electronic device. The wearable electronic device may be smart glasses 10_2a, a head mounted display 10_2b, a smart watch 10_2c, and the like.

The smart glasses 10_2a and the head mounted display 10_2b may include a display module that emits a display image and a reflector that reflects the emitted display screen and provides the display screen to a user's eyes, and may provide a virtual reality or augmented reality screen to the user.

The smart watch 10_2c includes a biometric sensor as an input device, and may provide biometric information recognized through the biometric sensor to a user through a display module.

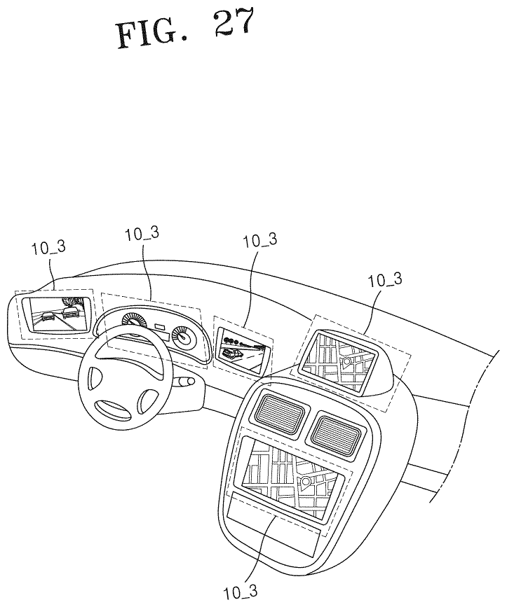

FIG. 27 illustrates a case where an electronic device including a display module is applied to a vehicle. For example, the electronic device 10_3 may be applied to an instrument panel, center fascia, and the like of an automobile, or may be applied to a Center Information Display (CID) disposed on a dashboard of an automobile or a room mirror display that replaces a side mirror. However, example embodiments are not limited thereto.

Although not shown, electronic devices to which display apparatuses according to some example embodiments are applied may include various home appliances that display information through display modules such as refrigerators, washing machines, dryers, air conditioners, robot cleaners, and the like, as well as devices mainly for screen display such as billboards, electronic signs, and game machines. However, example embodiments are not limited thereto. Also, when the display module has a function of transmitting light, the display module may be applied to electronic devices such as smart windows or transparent display apparatuses that display backgrounds and display images together. Types of electronic devices according to some example embodiments are not limited by the above examples, and applications of various other electronic devices not exemplified may also be possible.

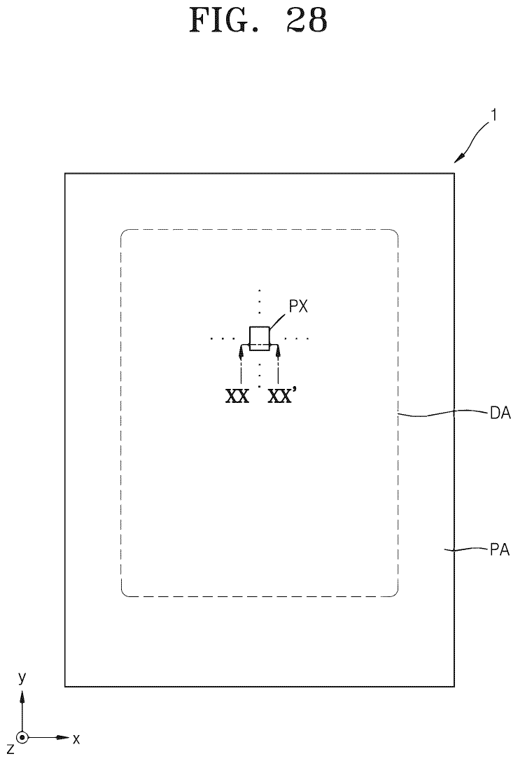

FIG. 28 is a schematic plan view of a display apparatus manufactured using an apparatus for manufacturing a display apparatus according to some example embodiments.

Referring to FIG. 28, the display apparatus 1 manufactured according to some example embodiments of the disclosure may include a display area DA and a peripheral area PA positioned outside the display area DA. The display apparatus 1 may provide an image through an array of a plurality of pixels PX two-dimensionally arranged in the display area DA.

The peripheral area PA is an area that does not provide an image, and may surround the display area DA entirely or partially. A driver and the like may be disposed in the peripheral area PA to provide electrical signals or power to pixel circuits corresponding to each of the pixels PX. A pad, which is an area where electronic elements or printed circuit boards may be electrically connected, may be disposed in the peripheral area PA.

Hereinafter, although the display apparatus 1 is described as including an organic light-emitting diode (OLED) as a light-emitting element, the display apparatus 1 of the example embodiments are not limited thereto. In some example embodiments, the display apparatus 1 may be a light-emitting display apparatus including an inorganic light-emitting diode, that is, an inorganic light-emitting display apparatus. The inorganic light-emitting diode may include a PN diode including materials based on an inorganic semiconductor. When a voltage is applied in a forward direction to the PN junction diode, holes and electrons are injected, and energy generated by recombination of the holes and electrons may be converted into light energy to emit light of a preset color. The above-described inorganic light-emitting diode may have a width of several to several hundred micrometers, and in some example embodiments, the inorganic light-emitting diode may be referred to as a micro LED. In some example embodiments, the display apparatus 1 may be a quantum dot light-emitting display apparatus.

The display apparatus 1 may be used as a display screen of various products such as televisions, laptops, monitors, billboards, internet of things (IoT) devices, as well as portable electronic devices such as mobile phones, smart phones, tablet personal computers, mobile communication terminals, electronic notebooks, electronic books, portable multimedia players (PMPs), navigation devices, Ultra Mobile PCs (UMPCs), and the like. Also, the display apparatus 1 according to some example embodiments may be used in wearable devices such as smart watches, watch phones, glasses-type displays, and head mounted displays (HMDs). Also, the display apparatus 1 according to some example embodiments may be used as an instrument panel of an automobile, a Center Information Display (CID) disposed on a center fascia or dashboard of an automobile, a room mirror display that replaces a side mirror of an automobile, entertainment for rear seats of an automobile, and a display screen disposed on a rear surface of front seats. However, example embodiments are not limited thereto.

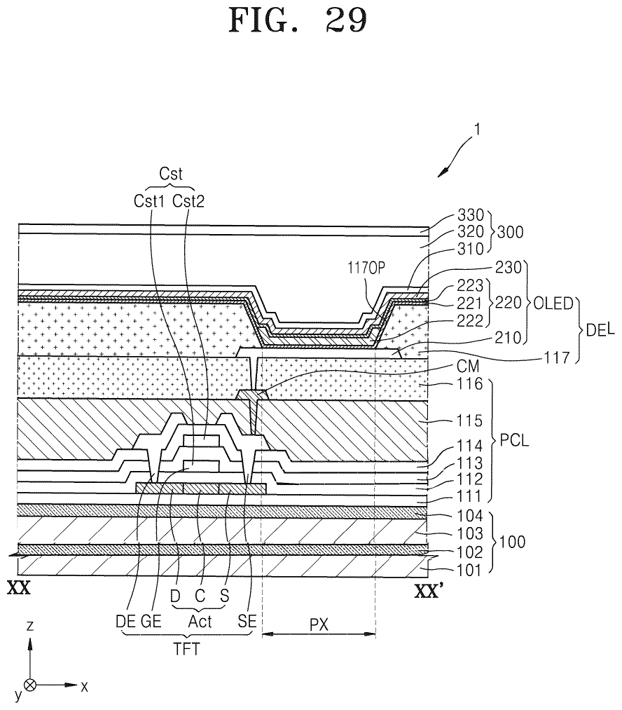

FIG. 29 is a schematic cross-sectional view of a display apparatus manufactured by an apparatus for manufacturing a display apparatus according to some example embodiments, and may correspond to a cross-section of the display apparatus taken along line XX-XX′ of FIG. 28.

Referring to FIG. 29, the display apparatus 1 may include a stacked structure of a substrate 100, a pixel circuit layer PCL, a display element layer DEL, and an encapsulation layer 300.

The substrate 100 may have a multilayer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 that are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP). However, example embodiments are not limited thereto. The first barrier layer 102 and the second barrier layer 104 may include inorganic insulating materials such as silicon oxide, silicon oxynitride, and/or silicon nitride. The substrate 100 may have flexible characteristics. However, example embodiments are not limited thereto.

A pixel circuit layer PCL is disposed on the substrate 100. FIG. 29 shows that the pixel circuit layer PCL includes a thin-film transistor TFT, and a buffer layer 111, a first gate insulating layer 112, a second gate insulating layer 113, an interlayer insulating layer 114, a first planarization insulating layer 115, and a second planarization insulating layer 116 disposed below and/or above components of the thin-film transistor TFT.

The buffer layer 111 may reduce or block penetration of foreign substances, moisture, or external air from below the substrate 100, and may provide a flat surface on the substrate 100. The buffer layer 111 may include inorganic insulating materials such as silicon oxide, silicon oxynitride, and silicon nitride, and may have a single layer or multilayer structure including the above-described materials. However, example embodiments are not limited thereto.

The thin-film transistor TFT on the buffer layer 111 includes a semiconductor layer Act, and the semiconductor layer Act may include polysilicon. Alternatively, the semiconductor layer Act may include amorphous silicon, an oxide semiconductor, an organic semiconductor, or the like. The semiconductor layer Act may include a channel region C and a drain region D and a source region S respectively disposed on both sides of the channel region C. The gate electrode GE may overlap the channel region C.

The gate electrode GE may include a low-resistance metal material. The gate electrode GE may include a conductive material including molybdenum (Mo), aluminum (Al), copper (Cu), titanium (Ti), and the like, and may be formed as a multilayer or single layer including the above materials. However, example embodiments are not limited thereto.

The first gate insulating layer 112 between the semiconductor layer Act and the gate electrode GE may include inorganic insulating materials such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may be zinc oxide (ZnO), and/or zinc peroxide (ZnO₂). However, example embodiments are not limited thereto.

The second gate insulating layer 113 may be provided to cover the gate electrode GE. The second gate insulating layer 113 may include inorganic insulating materials such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}), similar to the first gate insulating layer 112. The zinc oxide (ZnO_{X}) may be zinc oxide (ZnO), and/or zinc peroxide (ZnO₂). However, example embodiments are not limited thereto.

An upper electrode Cst2 of a storage capacitor Cst may be disposed on the second gate insulating layer 113. The upper electrode Cst2 may overlap the gate electrode GE below the upper electrode Cst2. In this case, the gate electrode GE and the upper electrode Cst2 overlapping with the second gate insulating layer 113 therebetween may form a storage capacitor Cst. That is, the gate electrode GE may function as a lower electrode Cst1 of the storage capacitor Cst.

In this way, the storage capacitor Cst and the thin-film transistor TFT may be formed to overlap. In some example embodiments, the storage capacitor Cst may be formed so as not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer of the above-described materials. However, example embodiments are not limited thereto.

The interlayer insulating layer 114 may cover the upper electrode Cst2. The interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may be zinc oxide (ZnO), and/or zinc peroxide (ZnO₂). The interlayer insulating layer 114 may be a single layer or multilayer including the above-described inorganic insulating materials. However, example embodiments are not limited thereto.

The drain electrode DE and the source electrode SE may each be positioned on the interlayer insulating layer 114. The drain electrode DE and the source electrode SE may be connected to the drain region D and the source region S through contact holes formed in insulating layers below the drain electrode DE and the source electrode SE, respectively. The drain electrode DE and the source electrode SE may include materials having good conductivity. The drain electrode DE and the source electrode SE may include conductive materials including molybdenum (Mo), aluminum (Al), copper (Cu), titanium (Ti), and the like, and may be formed as a multilayer or single layer including the above materials. However, example embodiments are not limited thereto. According to some example embodiments, the drain electrode DE and the source electrode SE may have a multilayer structure of Ti/Al/Ti.

The first planarization insulating layer 115 may cover the drain electrode DE and the source electrode SE. The first planarization insulating layer 115 may include organic insulating materials including general-purpose polymers such as polymethylmethacrylate (PMMA) and polystyrene (PS), polymer derivatives having phenolic groups, acrylic polymers, imide polymers, aryl ether polymers, amide polymers, fluorine polymers, p-xylene polymers, vinyl alcohol polymers, and blends thereof. However, example embodiments are not limited thereto.

The second planarization insulating layer 116 may be disposed on the first planarization insulating layer 115. The second planarization insulating layer 116 may include the same material as the first planarization insulating layer 115, and may include organic insulating materials such as general-purpose polymers such as polymethylmethacrylate (PMMA) and polystyrene (PS), polymer derivatives having phenolic groups, acrylic polymers, imide polymers, aryl ether polymers, amide polymers, fluorine polymers, p-xylene polymers, vinyl alcohol polymers, and blends thereof. However, example embodiments are not limited thereto.

A display element layer DEL may be disposed on the pixel circuit layer PCL having the above-described structure. The display element layer DEL includes an organic light-emitting diode (OLED) as a display element (e.g., a light-emitting element), and the organic light-emitting diode (OLED) may include a stacked structure of a pixel electrode 210, an intermediate layer 220, and a common electrode 230. The organic light-emitting diode (OLED) may emit, for example, red, green, or blue light, or may emit red light, green light, blue light, or white light. The organic light-emitting diode (OLED) emits light through a light-emitting area, and the light-emitting area may be defined as a pixel PX.

The pixel electrode 210 of the organic light-emitting diode (OLED) may be electrically connected to the thin-film transistor TFT through contact holes formed in the second planarization insulating layer 116 and the first planarization insulating layer 115 and a contact metal CM disposed on the first planarization insulating layer 115.

The pixel electrode 210 may include conductive oxides such as indium tin oxide (ITO), indium zinc oxide (IZO), zinc oxide (ZnO), indium oxide (In₂O₃), indium gallium oxide (IGO), or aluminum zinc oxide (AZO). In some example embodiments, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In some example embodiments, the pixel electrode 210 may further include a film formed of ITO, IZO, ZnO, or In₂O₃ above/below the above-described reflective film. However, example embodiments are not limited thereto.

A pixel-defining layer 117 having an opening 117OP exposing a central portion of the pixel electrode 210 is disposed on the pixel electrode 210. The pixel-defining layer 117 may include organic insulating materials and/or inorganic insulating materials. The opening 117OP may define a light-emitting area of light emitted from the organic light-emitting diode (OLED). For example, a size/width of the opening 117OP may correspond to a size/width of the light-emitting area. Therefore, a size and/or width of the pixel PX may depend on a size and/or width of the opening 117OP of the corresponding pixel-defining layer 117.

The intermediate layer 220 may include an emission layer 222 formed to correspond to the pixel electrode 210. The emission layer 222 may include polymer or low molecular weight organic materials that emit light of a desired (and/or alternatively predetermined) color. Alternatively, the emission layer 222 may include inorganic light-emitting materials or quantum dots.

According to some example embodiments, the intermediate layer 220 may include a first functional layer 221 and a second functional layer 223 respectively disposed below and above the emission layer 222. The first functional layer 221 may include, for example, a Hole Transport Layer (HTL), or may include a hole transport layer and a Hole Injection Layer (HIL). The second functional layer 223 is a component disposed above the emission layer 222, and may include an Electron Transport Layer (ETL) and/or an Electron Injection Layer (EIL). The first functional layer 221 and/or the second functional layer 223 may be common layers formed to entirely cover the substrate 100, similar to the common electrode 230 to be described below.

The common electrode 230 is disposed on the pixel electrode 210 and may overlap the pixel electrode 210. The common electrode 230 may be made of a conductive material having a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof. Alternatively, the common electrode 230 may further include a layer such as ITO, IZO, ZnO, or In₂O₃ on the (semi)transparent layer including the above-described materials. However, example embodiments are not limited thereto. The common electrode 230 may be integrally formed to entirely cover the substrate 100.

The encapsulation layer 300 is disposed on the display element layer DEL and may cover the display element layer DEL. The encapsulation layer 300 includes at least one inorganic encapsulation layer and at least one organic encapsulation layer, and as some example embodiments, FIG. 6 shows that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. However, example embodiments are not limited thereto. The organic encapsulation layer 320 may include polymer-based materials. Polymer-based materials may include acrylic resins, epoxy resins, polyimide, polyethylene, and the like. However, example embodiments are not limited thereto. According to some example embodiments, the organic encapsulation layer 320 may include acrylate. The organic encapsulation layer 320 may be formed by curing monomers or applying polymers. The organic encapsulation layer 320 may have transparency.

Although not shown, a touch sensor layer may be disposed on the encapsulation layer 300, and an optical functional layer may be disposed on the touch sensor layer. The touch sensor layer may acquire coordinate information according to external input, such as touch events. The optical functional layer may reduce reflectance of light (external light) incident toward the display apparatus from outside, and/or may improve color purity of light emitted from the display apparatus. According to some example embodiments, the optical functional layer may include a retarder and/or a polarizer. The retarder may be of a film type or a liquid crystal coating type and may include a λ/2 retarder and/or a λ/4 retarder. The polarizer may also be a film type or a liquid crystal coating type. The film type may include a stretched synthetic resin film, and the liquid crystal coating type may include liquid crystals arranged in a desired (and/or alternatively predetermined) arrangement. The retarder and polarizer may further include a protective film.

According to some example embodiments, a protective layer may be disposed between the encapsulation layer 300 and the touch sensor layer. The protective layer may be formed by injecting and curing a filler between the encapsulation layer 300 and the touch sensor layer.

An adhesive member may be disposed between the touch sensor layer and the optical functional layer. The adhesive member may employ general ones known in the art without limitation. The adhesive member may be a pressure sensitive adhesive (PSA).

According to embodiments of the disclosure, a filler between a display substrate and a touch screen panel may spread quickly and evenly, and quality of a display apparatus may be improved.

Effects of the disclosure are not limited to the effects mentioned above, and other effects not mentioned will be clearly understood by those skilled in the art from the description of the claims.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a chamber;
a first stage unit inside the chamber;
a second stage unit facing the first stage unit;
a panel receiving unit between the first stage unit and the second stage unit, and the panel receiving unit configured to support a bonding panel; and
a cylinder configured to move up to press the first stage unit toward the second stage unit,
wherein
as the cylinder moves up, the first stage unit moves up to contact the panel receiving unit, and
the first stage unit and the panel receiving unit are configured to move up together to press the bonding panel between the first stage unit and the second stage unit.

2. The apparatus of claim 1, wherein the panel receiving unit comprises:
a frame having an opening area in a center of the frame;
a panel holder on the frame, and the panel holder configured to support the bonding panel; and
a panel adjustment unit on the frame,
wherein the panel adjustment unit is configured to advance toward the opening area as the panel receiving unit is raised to align the bonding panel.

3. The apparatus of claim 2, wherein a plurality of panel adjustment units are spaced apart from each other along a circumference of the frame.

4. The apparatus of claim 3, wherein
the panel receiving unit further comprises a plurality of panel holders, and
the plurality of panel adjustment units and the plurality of panel holders are alternately arranged.

5. The apparatus of claim 2, wherein the panel adjustment unit comprises:
a moving plate on the frame, the moving plate configured to advance or retreat toward the opening area; and
a cam bearing at one end of the moving plate.

6. The apparatus of claim 5, wherein the second stage unit comprises:
a second base plate; and
a cam around the second base plate and the cam extending downward,
wherein the cam is on a vertical movement path of the cam bearing.

7. The apparatus of claim 6, wherein the cam comprises:
a flat portion extending vertically from the second base plate; and
an inclined portion having an inclined surface, the inclined surface being inclined with respect to the second base plate,
wherein
the cam bearing is configured to raise along the inclined portion as the panel receiving unit moves up, and
the moving plate is configured to advance inward as the panel receiving unit moves up.

8. The apparatus of claim 2, wherein
the first stage unit comprises a first base plate and a first stage on the first base plate,
a circumference of the first base plate is configured to contact a circumference of the frame as the cylinder raises, and
the first stage is configured to penetrate the opening area of the frame as the cylinder raises to contact the bonding panel supported by the panel holder.

9. The apparatus of claim 1, wherein the first stage unit comprises:
a first base plate;
a first stage spaced apart on the first base plate; and
a plurality of support columns between the first base plate and the first stage.

10. The apparatus of claim 9, wherein the plurality of support columns are spaced apart in a first direction and a second direction, the second direction crossing the first direction.

11. The apparatus of claim 9, wherein the plurality of support columns are in a lattice form.

12. The apparatus of claim 9, wherein the first stage comprises a plurality of protrusions protruding toward the second stage unit.

13. The apparatus of claim 12, wherein a surface of the second stage unit facing the plurality of protrusions is a flat plane.

14. The apparatus of claim 1, wherein
each of the first stage unit and the second stage unit further comprises a heater, and
each of the first stage unit and the second stage unit are configured to preheat a lower surface and an upper surface of the bonding panel, respectively.

15. A method of manufacturing a display apparatus, the method comprising:
seating a bonding panel, the bonding panel comprising
a first panel,
a second panel,
a filler injected between the first panel and the second panel, and
a dam unit along a circumference of the first panel in a panel receiving unit;
raising a cylinder to raise a first stage unit;
further raising the cylinder to raise the first stage unit and the panel receiving unit together; and
further raising the cylinder toward a second stage unit and pressing the bonding panel seated in the panel receiving unit with the first stage unit and the second stage unit.

16. The method of claim 15, wherein the pressing the bonding panel further comprises operating the first stage unit, the second stage unit, and the panel receiving unit by mechanical interlocks without separate controls as the cylinder raises.

17. The method of claim 15, wherein the panel receiving unit comprises:
a frame having an opening area in a center of the frame;
a panel holder on the frame, the panel holder supporting the bonding panel; and
a panel adjustment unit on the frame,
wherein the panel adjustment unit is configured to advance toward the opening area as the panel receiving unit is raised to align with the bonding panel.

18. The method of claim 15, wherein
the first stage unit is configured to contact one surface of the bonding panel,
the first stage unit comprises a protrusion protruding toward the second stage unit, and
the protrusion is within the dam unit of the bonding panel in a plan view.

19. The method of claim 18, wherein the second stage unit contacting another surface of the bonding panel comprises a flat plane.

20. An apparatus for manufacturing an electronic device, the apparatus comprising:
a chamber;
a first stage unit inside the chamber;
a second stage unit facing the first stage unit;
a panel receiving unit between the first stage unit and the second stage unit, and the panel receiving unit configured to support a bonding panel; and
a cylinder configured to move up to press the first stage unit toward the second stage unit,
wherein
the first stage unit is configured to move up as the cylinder moves up to contact the panel receiving unit, and
the first stage unit and the panel receiving unit are configured to move up together as the cylinder moves up to press the bonding panel between the first stage unit and the second stage unit.
